(19) United States
(12) Patent Application Publication
(10) Pub. No.: US 2012/0288641 A1
(43) Pub. Date: Nov. 15, 2012

(54) SYSTEM AND METHOD FOR DEPOSITING MATERIAL ON A PIEZOELECTRIC ARRAY

(76) Inventors: Deda Mampuya Diatezua, WELLINGTON, FL (US); Rainer Schmitt, PALM BEACH GARDENS, FL (US); Roland Williams, MARTINEZ, CA (US)

(21) Appl. No.: 13/442,380

(22) Filed: Apr. 9, 2012

Related U.S. Application Data
(60) Provisional application No. 61/516,839, filed on Apr. 8, 2011.

(51) Int. Cl. H01L 41/24; B05D 3/06; B05D 5/12

(52) U.S. Cl. 427/555; 118/696; 427/100

(57) ABSTRACT

A system having a print head for depositing material on a piezoelectric array, where the print head and array are moveable with respect to each other, and a computer for controlling movement of the print head and array with respect to each other to locations along the array, and controlling the print head to dispense the material onto the array at such locations. The print head deposits a pre-determined amount of material in one of dots, or in a line with movement of the print head and array with respect to each other. The system enables deposit of conductive material for electrical connections to array elements. Non-conductive polymer material may be deposited on the array before depositing conductive material to create barriers avoiding unintended connection of array elements by the conductive material. The system may also be used for fabricating a piezoelectric array by depositing electro-ceramic material.

This application claims the benefit of priority to U.S. Provisional Patent Application No. 61/516,839, filed Apr. 8, 2011, which is herein incorporate by reference.

### FIELD OF THE INVENTION

This present invention relates to a system and method for the depositing material on a piezoelectric array, and particularly to, a system for depositing material by a print head along a piezoelectric array of elements of electro-ceramic composite material of a 1-3 type or higher order. The system is useful for depositing conductive material for making desired electrical connections to array elements in one or more layers. The system may also deposit non-conductive polymer material on the array before depositing conductive material if needed to create barriers that avoid unintended connections of array elements by the conductive material when deposited. The system may also be used for fabricating a piezoelectric array by depositing electro-ceramic material to build-up array elements. The invention avoids thin metal film deposition based photo-lithography process as commonly used in the manufacture of semiconductors, which has been found difficult in the manufacture of electro-ceramic composite materials in dense arrays for piezoelectric fingerprint sensors. This inventions described herein represent improvements in manufacturing biometric sensing devices as described in U.S. Pat. No. 7,489,066, which is herein incorporated by reference.

### BACKGROUND OF THE INVENTION

The miniaturization of electronic components and increasingly dense levels of integration have resulted in the evolution of processes to deposit electrical conductors used to interconnect individual elements. The greatest progress has, of course, been made in the semiconductor industry where lithographic processes are used to define the pathways for the conductors and the conductors themselves can be deposited in any of a number of ways. For example, a metal conductor may be deposited using a sputtering process wherein a plasma is created in an inert, low-pressure gas environment and metal atoms released from a pure metal target, being one of two electrodes sustaining the plasma, are able to condense on the intended point of deposition, usually a substrate. Another method common in the semiconductor world is to bombard the recipient semiconductor wafer with ions to alter the conductivity of the semiconductor itself. Many kinds of material may be deposited using these kinds of techniques including insulator and semiconductor materials.

When the recipient of the material to be deposited is a flat, crystalline or amorphous substrate, an exemplar process would be a photo-lithographic process and is considered to be relatively straightforward. In this example, the substrate is first coated with a suitable photo-resist of which many types are commercially available. A photographic mask will have been prepared which mask will define the intended layout of the pattern of the material which is to be deposited on the substrate. The photo-mask will be at the actual scale of the geometry of the intended part. The photo-resist is normally applied to the substrate and dried, often by baking. Considerable pains must be taken to assure an even coating of consistent thickness to ensure even exposure. The photographic mask is then placed over the resist-coated substrate and the pattern exposed using a high energy light source, often ultra-violet. The short wavelength of the light is beneficial in that it allows good edge definition for the exposed pattern. The photo-resist is developed and the unwanted resist is stripped away and then the prepared substrate may be placed in the deposition machine. The metal atoms will be deposited over the entire substrate but when the resist covered areas are finally removed, this leaves a conductor pattern on the substrate joining the required elements together electrically.

When the substrate exhibits a high degree of flatness, the process can be engineered to work reliably and repeatably but, when surface flatness is uncertain then the quality of the deposited material may vary to the point that it is no longer a straightforward process. Uncertain variability in flatness generally leads to poor repeatability and compromised process yield. Steps in the height of the substrate material present significant problems; edges tend to exhibit poor coverage by the conductor and may prove to be points of failure when the item is stressed over temperature and current.

Composite materials, such as of lead zirconate titanate (PZT) material, present a particularly challenging difficulty. The different constituents of the composite material exhibit differing properties and a major hurdle to be overcome is change due to temperature variation. In particular when the composite is of a 1-3 type or higher order, then the material is defined as being continuous in one direction and the effects of temperature are severe. When a metal is applied to the surfaces, there can now be three different materials each with its own temperature sensitivities which further complicates the problem with the allowable temperature range for the part.

Moreover, the manufacturing process for certain composites involves very high temperatures during the formation or sintering of the piezoelectric material. Without very carefully controlled cooling from such high temperatures, distortion is a significant problem which can be difficult or even impossible to correct in any subsequent step. This introduces dimensional variability into the final composite structure that limits the use of photo-lithographic semiconductor technologies because the substrate often exceeds allowable limits such as the spacing consistency between elements or flatness. A photographic process, being of fixed dimensions, may be difficult to apply reliably with consequential yield constraints. The use of a polymer in the composite further limits the subsequent allowable process temperature, and it is apparent that alternate technologies would be desirable to overcome these difficulties.

U.S. Pat. No. 7,489,066 describes a biometric sensing device of an array of discrete piezo electro-ceramic elements and filler there between. The array of discrete electro-ceramic elements is responsive to acoustic characteristics of parts of the finger. Conductors are provided along the array enable signals to be received from individual sensing elements which are processed to provide a fingerprint image. During manufacturing of the device such conductors may be applied by thin metal film deposition based photo-lithography which has been found to have the above-described problems due variability in array elements dimension and/or the flatness of the surface of the arrays when conductors are applied. Moreover, the photo-lithographic process may be unusable if the piezo electro-ceramic array is large, such as 55 mm×55 mm or larger.

### SUMMARY OF THE INVENTION

Accordingly, it is an object of the present invention to improve manufacturing of piezoelectric sensor arrays by providing a system and method for depositing conductors onto electro-ceramic composite arrays by printing, e.g., by an ink-jet printer or print head, of conductive material(s) onto electro-ceramic composite array to provide such conductors, thereby avoiding the drawbacks of photo-lithographic deposition of conductors.

A further object of the present invention is to first apply non-conductive material, such as a polymer, prior to depositing conductive material in order to create barriers avoiding unintended connection of array elements by the conductive material when deposited.

It is another object of the present invention to fabricate an electro-ceramic composite array by printing electro-ceramic composite material at array locations in forming array elements of desired height.

Briefly described the invention embodies a system having a print head, such as ink-jet type print head, for depositing a material on a piezoelectric array of elements composed of electro-ceramic composite material, a mechanism for moving the print head and the array with respect to each other, and a computer for controlling the mechanism to move the print head and the array with respect to each other to locations along the array, and controlling the print head to dispense the material onto the array at such locations.

The print head when actuated deposits a pre-determined amount of material responsive to signals from the computer in one of dots (drops), or along traces or lines in accordance with movement of the print head and the array with respect to each other. Preferably, the print head is movable by the mechanism in multiple dimensions over the array which is disposed stationary on a surface, plate, or substrate. The material deposited by the system may be a conductive fluid, such as conductive metallic ink, or non-conductive fluid, such as a liquid polymer. The array represents a matrix of pillar-like structures of electro-ceramic material of desired size, height, and density of distribution, with a flexible filler material, e.g., epoxy, binding the structures together, and a generally flat surface provided along the surfaces of the pillar-like structures and the flexible filler material there over which the print head may be selectively located.

When the material being deposited is a conductive fluid, the system enables the print head to deposit the material directly onto the composite array so as to make the electrical connections to the individual elements of the array. Thus conductive elements or conductors may be deposited by the print head on the array under control of the computer, rather than by metal film deposition based photo-lithography process. The material applied conforms to the surface of the composite material of the array. Preferably, the conductive elements are deposited in a first layer of locations in traces or lines (generally parallel to each other) along the surface of the array over array element(s) and filler material between array elements, and then in a second layer of locations of array elements in drop(s) to provide enlarged areas for contact points. Thus, one or more layers of the conductive material may be provided at such locations, where each layer of material at locations is provided in a separated pass or path of the print head over the array. The viscosity of the conductive fluid enables the desired conductor line width or contact point size to be provided by the print head when actuated by the computer system.

Different materials may be deposited by the print head at different times. For example, the system may be operated in first and second modes. In the first mode, the print head deposits non-conductive material, such as a polymer, at a first plurality of locations representing locations between adjacent different ones of array elements to provide a polymer layer. After the polymer fluid polymerizes, the system then operates in the second mode to provide conductive material in one or more layers in which the print head deposits conductive material, such as conductive ink, along the array in one or more of traces or drops to provide connections at a second plurality of locations representing locations along different ones of the elements of the array. The non-conductive material when deposited creates separators or barriers to avoid unintended or unwanted connection of array elements by conductive material by flow or wicking.

The present invention also provides a method for the depositing material using a print head on a piezoelectric array of elements composed of electro-ceramic composite material by selectively printing conductive material along the array to provide connections along different ones of the elements of the array. The method may further provide for printing non-conductive material between adjacent ones of the array elements prior to printing with conductive material. The non-conductive material deposited prevents connection of deposited conductive material to one or more of the elements of the array when the printing conductive material step is carried out.

The printing, such as by ink-jet printer, of the present system and method solves the problem of forming conductors along arrays by thin metal film deposition based photo-lithography process, described earlier, which is difficult to reliably provide conductor elements due to variability in array elements dimensions and/or the flatness of the surface of the arrays when conductors are applied among elements in the same array, and/or among different arrays.

In applying conductor elements for an array for use in a finger print sensing device, the system operates separately with respect to top and bottom of the same array to deposit conductor elements along the top and bottom array surfaces, respectively. The system may operate upon one or multiples arrays at one time.

The system of the present invention may be used as part of the fabrication method of an electro-ceramic composite array itself. Such method provides printing electro-ceramic composite material in dots or drops upon a substrate at array locations to a height greater than a target thickness of the array to provide elements of the array, sintering each of the elements of the array (such as by a laser), applying filler material between and over the elements, and grinding the array along the top thereof down until the target array thickness upon the substrate is reached. Thereafter, the completed array may have conductive material (or non-conductive material and then conductive material) applied by the system onto the array as described above.

In summary, the system of the present invention relates generally to the deposition of materials on the surfaces of an electro-ceramic array prepared as a 1-3 composite. Typically, a multi-element transducer for pressure waves such as sound or ultrasound, or indeed any transducer assembly that couples mechanical motion and an applied or derived electric potential, involves making more than one electrical connection to each of the elements. In an array of elements, one connection may be shared between some or all elements, for example, a common ground connection.

Dense arrays of piezoelectric sensors may be fabricated by creating a matrix of individual sensors. Such arrays may be used for scanning, for example, surface features which may be in contact with the array; one class of application of this type would be the contact sensing of fingerprints or other skin features. In one example, a matrix of electro-ceramic elements are bound in a polymer structure, e.g., epoxy, so that the active elements are all aligned but separated and spaced regularly throughout the polymer. The array may be prepared as a single row or as a field of sensors as described in the above incorporated U.S. Pat. No. 7,489,066. The array elements may be connected by conductors located on the top and bottom of the matrix so that each element is individually addressable and so that each element may be activated independently of its neighbors in the array.

Conductive elements such as conductive ink or fluid, may be printed directly onto the composite array so as to make the connections to the individual sensors. The conductive ink or fluid may be sintered or cured after application. The viscosity of the ink is such as to provide the desired thin width or dot size and to minimize undesirable flow or wicking. The conductor may be the result of the application of more than one layer of the conductive ink or fluid. The ink or fluid may be selected so as to conform well to the surface of the composite material. The requirement for flatness of the array which is normally dictated by the photo-lithographic process may be relaxed because the need for intimate contact between a mask and a coating layer is removed. The need for close control of surface irregularities may be relaxed because the conductive ink may fill small voids or surface imperfections. The fill performance may be adjusted by the formulation of the ink.

Ink may spread over the substrate out of the boundary of the set line width. Depending on the conductive ink used, ultraviolet (UV) light or high power light source, including but not limited to a laser, may be used to partially or totally sinter the ink when being printed. Such that ink which is sensitive to UV light, the UV light dries ink so that it does not expand. Metal lines confinement within specified width is thus obtained. Other light sources, an oven, or other means to promote desired melting and/or sintering of the conductive ink deposited may also be used as specified by the conductive ink manufacturer.

As stated earlier, one or more conductive layers may be printed by the system of the present invention onto the array in traces and as connection or contact points for electrical signals to/from individual array elements via such traces. One or more layers may also be directly printed over the one or more conductive layers to act as passivation layers. Further, one or more auxiliary layers (e.g., coatings) may be directly printed onto the array so as to act as matching layers between the array and its environment. An accurate acoustic match may improve the performance of the array according to the application. Also, additional layers may be directly printed, in whole or in part, onto the array to serve as spacing layers.

Although the system is directed to depositing material onto an array of electro-ceramic composite material, and in particular 1-3 electro-ceramic composite, the system may also be used for depositing material onto any other substrate.

### DETAILED DESCRIPTION OF THE DRAWINGS

The foregoing objects, features and advantages of the invention will become more apparent from a reading of the following description in connection with the accompanying drawings, in which:

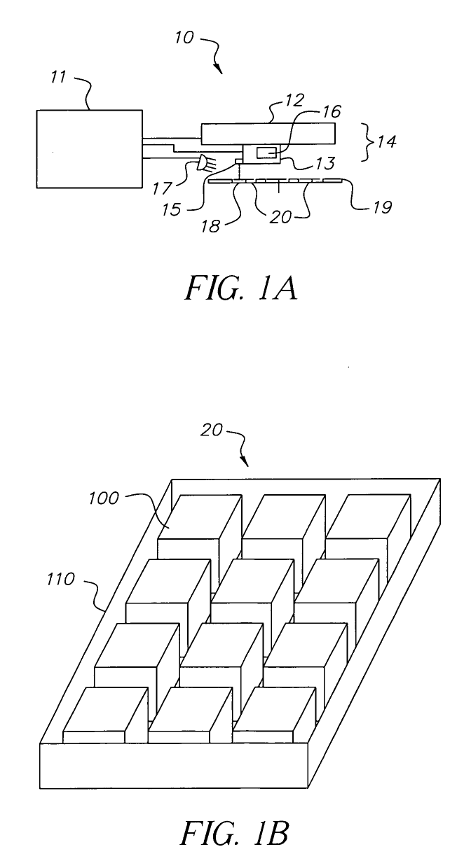

FIG. 1A is a block diagram of the system of the present invention;

FIG. 1B is a partial perspective view of part of the rectangular 1-3 electro-ceramic composite array of FIG. 1A before material is deposited by the system upon the array;

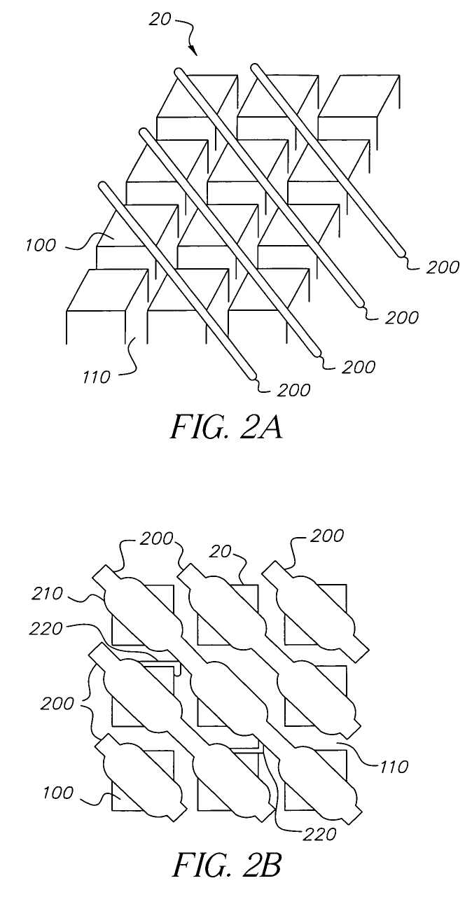

FIG. 2A is similar to FIG. 1B showing an example of material deposited in diagonal traces, or generally parallel lines, along the array by the system of FIG. 1A;

FIG. 2B is a top view of an example of a three by three element array of FIG. 1A showing in more detail the connections to array elements when material, such as conductive material, deposited in diagonal traces or lines to make electrical connections to elements along the array, for use of the array as part of a finger print sensor and with additional material deposited along individual array elements to assure proper contact or connection thereto;

FIG. 2C is a top view of the array of FIG. 1A showing schematically an example of material deposited along horizontal and vertical traces or lines by the system of FIG. 1A for use of the array as part of a finger print sensor;

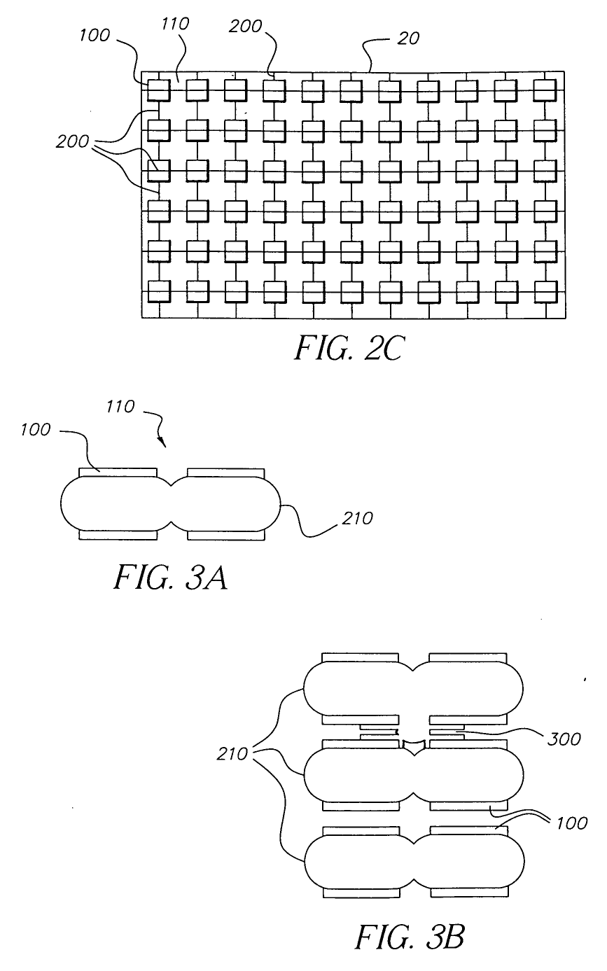

FIG. 3A is a more detailed top view of two adjacent array elements of the array of FIG. 2C by conductive material deposited by the system of FIG. 1A to make a connection between array elements;

FIG. 3B is a top view of six adjacent array elements of the array of FIG. 2C illustrating undesirable wicking effect flow causing unintended connection along the ceramic-polymer interface between the elements by deposited material by the system of FIG. 1 when fluid viscosity of the deposited material is too low;

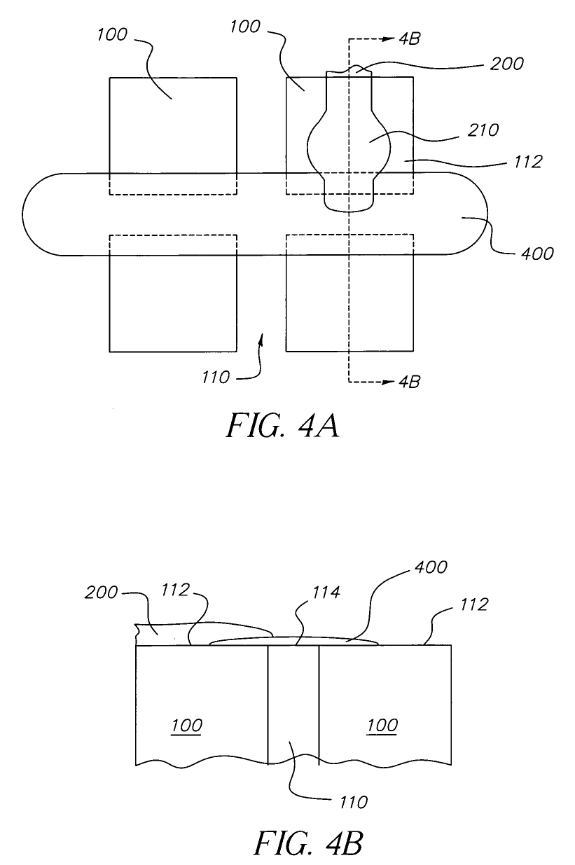

FIG. 4A is a top view of four adjacent array elements of the array of FIG. 1A illustrating the deposit of a non-conductive separator or barrier member in the case where the non-conductive separator or barrier member when applied flow or wicks over adjacent array elements;

FIG. 4B is a cross-sectional view along lines 4B-4B of FIG. 4A; and

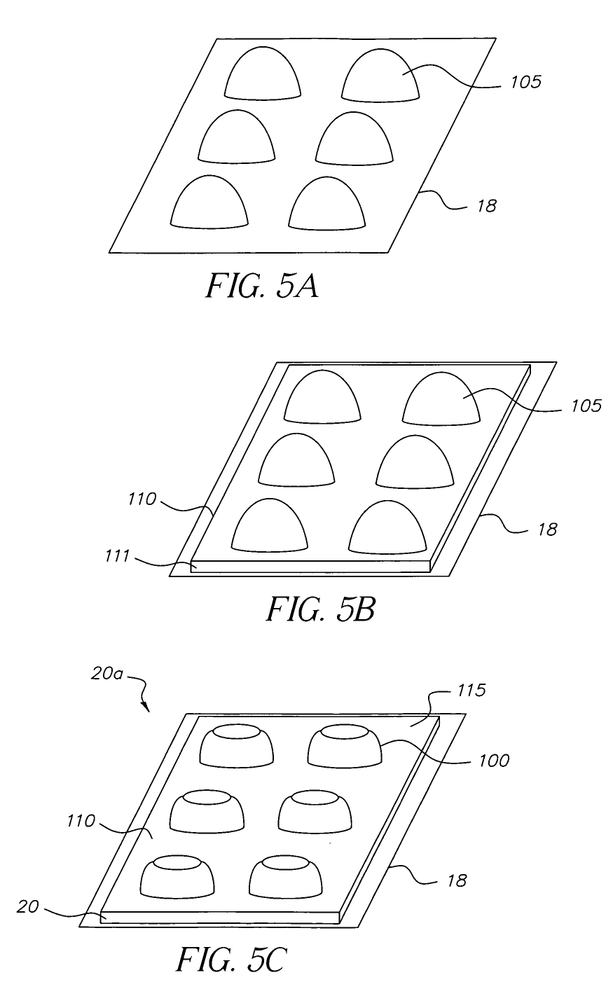

FIGS. 5A, 5B, and 5C are perspective views the process of fabricating an array electro-ceramic material using the system of FIG. 1A, where FIG. 5A shows a substrate or plate onto which the array of FIG. 1A is formed by dots or drops of electro-ceramic composite material from the print head at desired array element locations, FIG. 5B shows the dots or drops after being sintered and filler material is provided, and FIG. 5C shows the array when ground (or substantially leveled) to a target array thickness.

### DETAILED DESCRIPTION OF THE INVENTION

Referring to FIG. 1A, a block diagram of the system 10 of the present invention is shown having a print head 13 of an ink-jet type with a plurality of nozzles, such as numbering 16 or 128. The print head 13 may be a part of a cartridge 16 providing a reservoir with fluidic material for dispensing from the print head 13, as typical of an ink-jet type print head. A separate reservoir or container may also be used, rather than cartridge 16 to provide fluidic material to print head 13. Print head 13 is movable by a drive mechanism 12 in multiple dimensions, such as orthogonal x,y,z, directions in which z is towards and way from the x,y plane of a surface, plate, or substrate 18 supporting one or more arrays 20 of electro-ceramic composite material. Preferably, each array 20 is held or retained upon surface 18 by a fixture 19 having rectangular openings each sized to receive one of arrays 20. For purposes of illustration, three arrays 20 are shown, but one or other number of arrays 20 may be provided.

An example of array 20 is shown in FIG. 1B of electro-ceramic composite material comprising individual piezoelectric elements 100 bound into a regular array by a filler material 110, such as an epoxy or polymer (e.g., araldite and if needed air filled vinyl micro-spheres). Array 20 can be made from lead zirconate titanate (PZT) material having ceramic rectangular (tower or pillar-like) elements in a matrix. The electro-ceramic elements of array 20 can have shapes other than rectangular, such as cylindrical or a partial tear drop shape (see FIGS. 5A-5C). The ceramic elements 100 are relatively hard and brittle material whereas the filler material 110 that fills the interstitial spaces between the ceramic elements 100 may be considerably softer and rather pliable. Such interstitial filler material 110 in addition to binding the array together also suppress any shear waves so as to increase acoustical attenuating and electrical isolation when conductors are applied as described herein. For purposes of illustration, the array of FIG. 1B is not shown to scale.

In a preferred embodiment, array 20 comprises rectangular piezoelectric elements 100 that are 40 microns square by 100 microns deep, thereby yielding a dense array 20 having a 20 MHz fundamental frequency sonic wave elements. A spacing of 10 microns is used between elements is preferred in order to provide a 50-micron pitch between elements. Other geometries may be used, such as for example, a pitch of greater than 50 microns.

Array 20 may be manufactured in the same manner as described in the above incorporated patent before placement of conductors, such as by laser cutting, dicing, molding, or screen-printing. Laser cutting involves using an excimer laser to cut small groves and thereby form the elements of array 20. Dicing involves using high performance dicing equipment to form groves and the elements of array 20. Molding involves using injection molding equipment to form array 20, such as from a ceramic slurry. Screen-printing is a technique similar to that of solder printing in the assembly of printed circuit boards, where highly automated screen printing machines are adapted with laser cut stencils. The fabrication of array 20 may be the same as described in the above incorporated U.S. patent, except where the part of the fabrication process involving placement of conductive elements along the array 20, or other layer(s) as described herein, is provided by system 10. Array elements 100 may be shaped as shown by array 20a of FIG. 5C which is fabricated by system 10 as later described below, which may also be operated upon by system 10 in the same manner as described herein in connection with array 20.

The drive mechanism 12 may be an x, y, z stage having a motor enabling bidirectional motion in each of the x, y, z dimensions (or axes). Alternatively, an x,y stage may be coupled to surface 18 for movement in at x, y dimensions instead of or in addition to mechanism 12.

A computer (computer system or controller) 11 has memory having a program or software for controlling operations the system 10. Computer system 11 sends signals to the drive mechanism 12 to move the print head 13 to desired locations and sends signals to enable actuation of the print head 13 to control dispensing of material provided from cartridge or reservoir via print head 13 onto array 20 when the drive mechanism is positioned in at x, y coordinates at such locations at a desired distance in z spaced there from. The memory of the computer system has a preset movement and dispensing sequence (or program) which the computer system 11 follows to provide material from print head 13 nozzle(s) onto the array 20 in the desired locations and amounts, such as to provide dot(s), or trace(s) or line(s), as desired. Different passes over the array 20 can be provided at the same or different locations for depositing layers of the same material or different material from print head 13.

The drop size for the print head 13 can be varied from 5 to 50 micron under control of the computer system 11, such as by selecting a subset of nozzles and/or actuation time of the print head 13. Step size by mechanism 12 in x and y dimensions may be in 5 microns or more, while in z dimension the print head can be moved in millimeter steps, such as to preferably 700 microns above the array 20. Thus, controlled dot(s), or trace(s) or line(s), of material from print head 13 can be provided by system 10 to enable material from print head 13 to be deposited upon one or more arrays 20 of FIG. 1.

The material which may be dispensed by print head 13 may be conductive fluids, such as conductive metallic ink, or a non-conductive fluid, such as a liquid polymer material. For example, conductive metallic ink may be conductive nanoparticles (e.g., silver) mixed together with a solvent so as to enable flow via ink jet nozzles of print head 13 when actuated by computer system 11. For example, the conductive metallic ink may be CCI-300 manufactured by Cabot Corp, but other conductive metallic inks may be used. Also other conductive or non-conductive materials may also be dispensed in other forms of a powder, a slurry, or a colloid having proper viscosity for dispensing via nozzles of print head 13 when actuated by computer system 11. To change the material dispensed in system 10 a different print head cartridge may be provided, or the same print head cartridge re-filled with a different desired material. Although a single print head 13 is shown, multiple print heads may be provided which move in tandem by the drive mechanism 12, or each separately attached to the drive mechanism 12 when needed to deposit its respective material there from under control of computer system 11.

One area that has seen enormous strides has been the development of very high quality printing machinery. The recent ability of equipment to deposit inks, fluids and colloids with high accuracy and repeatability to a recipient material such as a substrate material has meant that it is now possible to directly deposit materials as a positive process. For example, system 10 may utilize a high precision ink-jet printer 14, such as Fujifilm Dimatix ink-jet printer, model no. DMP5000. Such printer 14 provides print head positioning (in x,y or x,y,z) and actuation (i.e., printer 14 represents at least drive mechanism 12 and print head 13 coupled thereto), and hardware/software interface to computer system 11 enabling an operator to program the system 10 to apply material(s) from print head 13 at desired locations over surface 18. Other high-precision ink-jet printers may also be used.

In operation, the system 10 enables a conductive material via print head 13 to be deposited that is sufficiently tolerant of vertical features of the 1-3 composite material of array 20. This may sacrifice line edge definition such as may be provided by thin film deposition based upon photolithographic process in return for more robust step coverage and a reduction in the cleanliness requirements that are implicit in the photolithographic process. Further, simplification of the complexity associated with a vacuum deposition may be beneficial.

Referring to FIGS. 2A, 2B, 2C, and 3A, system 10 provides diagonal deposition of conductive ink 200 in traces as shown by parallel lines in FIGS. 2A and 2B, or orthogonal grid of different traces of conductive material along array 20, as shown in FIGS. 2C and 3A. FIG. 2B further shows the same conductive ink 210 being deposited by system 10 in one or more drops or droplets 210 from print head 13 to provide contact points. Preferably, all traces are made first at desired array locations along array elements 100 and filler material 110 there between of desired line width, such as 30 microns wide, in order to deposit a first layer or conductive material. Thereafter, at each location where a contact point or connection to array element 100 is needed, one or more drops 210 are deposited in order to deposit a second layer of conductive material. Preferably, such drop(s) are located upon each array element 100 where a contact point is desired so as to provide an oval shape of conductive material with such part of a trace of the first layer already present on that array element. Deposition of a layer may also be repeated, if needed. Depending on the viscosity and chemical composition of the ink 200 and print head 13 dispensing thereof a desired size (width) traces and contact points are provided. Good repeatability exhibited by high quality precision machinery, such as Fujifilm Dimatix ink-jet printer described above, provides repeated application can be used to buildup thickness in material layers in a very selective way as described herein.

In this manner, conductors being deposited in the first layer can be selectively thickened at array 20 locations corresponding to contact points on array elements 100 by the second layer. The deposited conductive material 100 results in conductors or conductive element interconnected in a grid (or lattice) as desired upon array 20, as shown for example in FIGS. 2B and 3C. After the first and second layers are deposited, one or more additional layers may be selective deposited by system 10, such as of photoresist material to provide passivation layer(s). Also coating material may be applied by system 10 in one or more layer(s), desired. The interconnected conductive elements may be assembled with other parts and further connected using similar direct deposition by system 10 of desired material(s).

Additionally, after depositing of the first and second layers of conductive ink 200, such layers are sintered to remove the solvent contained in the applied conductive ink. The type of sintering depends on the particular conductive ink used. For example, in the case of Cabot conductive ink mentioned earlier, the entire array 20 is placed in a convection oven, such as for 30 minutes to 1 hour, until the ink is sintered as specified by the manufacturer. In another less preferred example, the conductive ink may 200 be manufactured by Inktec Co., Ltd. of South Korea. Sintering with Inktec ink is by application of Ultraviolet (UV) light from a light source 17 (FIG. 1A), or other high power light source, during the print head 13 depositing of such conductive material, as specified by the manufacturer. Such sintering may be partial or total sintering as desired. Computer system 11 may optionally control the operation of light source 17. Other light sources, oven, or other means that increases temperature sufficient to promote desired melting and/or sintering of the conductive material may also be used as specified by the conductive ink manufacturer. It is believed that sintering by light source 17 during the deposition process may control the spread of the fluidic conductive material along the array 20 out of the predefined line boundary locations where deposition is desired, and thereby assist in confining conductors to a particular line width or dot size applied. If a light source is not needed for sintering (or curing) the particular ink, then light source 17 may be removed from system 10.

The deposited conductive material thus becomes a conductors or conductive elements enabling desired electrical contacts to array element 100 of the desired line width each to provide a sensing element as described in the above incorporated patent. As stated earlier multiple depositions by system 10 may be repeated at the same array locations (or paths, lines, or traces) in order to build-up layers of conductive material for passing electrical signals. Although the above layers are discussed with respect to the top of the array 20, after desired layers are provided by system 10 along the top of array 20 the entire array is flipped in fixture 19 so that bottom of the array 20 can be operated upon by system 10 to deposit the layers of material at the same locations as along the top of the array to make identical conductors (or deposit other layer(s) described herein) when the array is to be part of a fingerprint sensor as described in the incorporated patent.

In the case of a 1-3 electro-ceramic composite, the surface steps (or variations in surface flatness) between the two constituent materials filter material 110 and electro-ceramic material of array elements 100 may provide a channel where the surface tension of the ink, fluid or colloid when deposited by system 10 can causes diffusion in interstitial regions between adjacent array elements 100. In certain circumstances, as illustrated in FIG. 3B, and in FIG. 2 (bleeding 220 of conductive ink 200), such as close spacing of the array elements 100 and with very low viscosity of the fluid, the “wicking” effect may cause short circuits between adjacent conductors that may be impractical or impossible to correct. Regardless of surface cleanliness, the surface tension effect may be pronounced. The viscosity of the fluid deposited may be limited to a narrow working range because of the limitations of the active constraints of the deposition mechanism provided by print head 13.

Referring to FIGS. 4A and 4B, this problem may be overcome by application of separator or barrier member of insulator, non-conductive material 400 which is deposited by the system 10, via print head 13 with cartridge 16 having such non-conductive material, along the interstitial region(s) 114 between array elements 100 where no connection by a conductive element is desired. Preferably, non-conductive material 400 is a polymer material, and thus deposition thereof is referred to herein as of a polymer layer. Such polymer material may, for example be photoresist, dispensed by the print head 13. Once upon the array 20, the polymer material at least partially solidifies (by polymerization) to provide such polymer layer representing insulating barriers avoiding undesired connections between the particular array elements 100 separated by barriers when the conductive material 200 are later applied by system 10 at or near such array elements. Light source 17 may optionally be used during depositing of the non-conductive material by system 10. There may be a flow, bleeding or wicking of non-conductive material 400 as shown in FIGS. 4A and 4B partially over the top surface 112 of array elements 100. As such, the flow does not effect desired electrical connectivity to the array element 100 by conductor element 200, as best illustrated in FIG. 4B. Non-conductive material 400 may be deposited repeated at the same location if needed to build-up layers.

After the non-conductive polymer material is applied at locations to provide the desired non-conductive barriers, the two layers of conductive material 200 as described above are then deposited by system 10 at desired locations and amounts in one or more passes over array 20. The polymer layer preferably is then removed, such in a manner common to the semiconductor industry. However, removal of the polymer layer may be optional if such does not effect conductors or subsequent layers. With the conductor material 200 applied accurately by system 10 to adhere to the electro-ceramic of array 20, the non-conductive material 400 barriers enables conductor material when deposited by print head 13 to easily flow (or bleed) where needed to provided desired connections without the seeping effect seen at the interfaces of the example of FIG. 3B. The bleeding, if any, over array elements 100 may be different than shown in FIG. 4B by control of the line width or drop(s) of the non-conductive polymer material 400 deposited by system 10.

Because a composite material may show variation in size and relative placement of the array elements 100, especially array elements of electro-ceramic 1-3 composite material, the placement of the traces along the array 20 and connection points upon array elements 10 may vary. Accordingly, system 10 may use an optical aid for alignment prior to application of material by print head 13. Such alignment enables offset placement of print head 13 so that conductive material or non-conductive material when deposited is aligned so that each array element is connected desired regardless of the offset from its intended position of array elements 10. In the case where variation is linear across the dimensions of the surface, then the programmed placement may be linearly scaled; for example if the entire substrate is 5% larger or smaller due to process uncertainties in the early part of fabrication, then the programmed placement may be increased by the same linear 5%. However where local distortion has occurred, an optical alignment aid may be automated so as to scale individual connection points though at the cost of operating speed. This feature of system 10 permits far greater process variation that is possible using a photolithographic process where the photo mask is invariant and dimension of array elements 100, which often vary from expected position or size.

Preferably, the optical alignment aid is provided by pattern recognition software programmed in system 10 to apply material from print head 13 at positions where array structures 100 are present in array 20. A camera 15 may be mounted adjacent the print head, or in know offset spatial relationship thereto, to capture image(s) focused on the array 20 or parts thereof (see dotted line). When system 10 is programmed using computer system 11, the operator utilizing a user interface on computer system 11 (e.g., graphical user interface upon a display with keyboard, mouse or the like) provides the objects (size and/or boundaries) of each of the array elements in array 20, and the locations for each layer for material deposition by system 10, which is stored in memory of the computer system. As typical of pattern recognition software, camera 15 provides image(s) which are digitally processed to detect boundaries of objects, match array elements 100 as objects to their expected locations stored in memory, and adjusts print head location (offset) accordingly so placement of material is accurate. For example, such pattern recognition software and user interface software enabling programming of the operation of the high precision ink-jet printer 14 described above may be provided by the printer manufacturer.

System 10 may be used in addition to apply conductive material 200 or non-conductive barrier material 400 described above may be used to fabricate array 20, rather than by a fabrication methods described in the incorporated patent. In this case, the material dispensed by print head 13 is an electro-ceramic material deposited at locations to provide the desired array element size, spacing between array elements, and total array size, of the desired height. To produce the electro-ceramic material to be deposited, electro ceramic material (PZT) may be crushed or pulverized, and then following a drying process, the fine powder resulting may be combined with a binder (e.g., an epoxy) and the resulting fluid provided in the reservoir of a cartridge 16 installed in print head 13. The process to arrive at the fine powder of PZT material may be considered calcining. For example, FIGS. 5A, 5B, and 5C show the fabrication steps.

FIG. 5A shows a substrate or plate 18 onto which dot or drop(s) 105 from the print head of FIG. 1A of electro-ceramic composite material is deposited at array element locations. The dots are thus at locations where each tower-like element of the array is to be built. The thickness of the dots may each be a single dispensed drop or built up by repeated overprinting of multiple dots to greater than a target thickness (height upon substrate 18). The target thickness may be 100 microns. Once at least the target thickness (and size) of the dots 105 has been achieved, then sintering is performed, such as by dot by dot basis using a laser.

The sintering process preferably comprises a “flash” sintering whereby the targeted volume is brought very rapidly to sintering temperature and also cools rapidly. Where the electro-ceramic material so deposited contains lead as a significant component, one of the significant process concerns is the ablation of the lead during the soak at sintering temperature. This can be a lengthy process which may deplete the lead content severely and thus sacrifice many of the desirable properties of the electro-ceramic material. By controlling the time spent at sintering temperatures to the minimum needed, lead depletion may be substantially mitigated. Because the sintering no longer occurs in the bulk, warping and distortion may be reduced.

After sintering, filler material 110 (e.g., epoxy) is added over the dots 105 and regions there between to provide a rectangular block 111 as shown in FIG. 5B. Once filler material 110 polymerizes, grinding along the top of block 111 then is performed to reduce the thickness of the block and provided finished array 20a with the target height and a sufficiently flat surface 115, as shown in FIG. 5C, so that the top of each array element of the desired size is present along surface 115. It is desired that the top array surface of array 20a (or array 20) has as little variability, but system 10 can accurately apply material(s) along an array surface even with thickness or dimensional variation which is on average 400 nm. Deposit of materials by system 10 thus has more tolerance to variability of the surface flatness than photolithographic depositing of conductive material, and thus system 10 deposition does not have the disadvantages described earlier of less preferred photolithographic metal deposition.

With the array 20a fabricated by system 10, system 10 may then be utilized to deposit the first and second conductive layers as described earlier on the fabricated array 20a in the same manner as array 20 to make traces and connection points, and if desired a polymer layer prior to depositing such conductive layers.

The substrate 18 with drops 105 formed thereupon is preferably removed from placement below print head 13 for carrying out the sintering process, such as by mounting the substrate 18 to a laser mounted stage positional over each dot 105 (or group of dots) for the desired duration and cross-sectional spot size. After addition of filler material 100, the resulting block 111 is presented to a grinding machine to provide array 20a of FIG. 5C. The array may then be placed back upon surface 18 in fixture 19 under the print head 13 of system 10 for depositing conductive material 200 (with or without non-conductive barriers) as described earlier.

The deposition of material as a printing process by system 10 as illustrated for example in FIGS. 5A-5C facilitates the production of uniquely shaped piezoelectric elements and combination of elements of the same or different geometric shapes or size.

From the foregoing description it will be apparent that there has been provided an improved system and method for system and method for the depositing material (conductive or non-conductive) on a piezoelectric array and for fabricating such array. The illustrated description as a whole is to be taken as illustrative and not as limiting of the scope of the invention. Such variations, modifications and extensions, which are within the scope of the invention, will undoubtedly become apparent to those skilled in the art.

1. A system for depositing material on a piezoelectric array of elements composed of electro-ceramic composite material comprising:
a print head for depositing a material on the array;
means for moving said print head and the array with respect to each other; and
a computer system for controlling said means to move said print head and the array with respect to each other to locations along the array, and controlling said print head to dispense said material onto the array at the locations.

2. The system according to claim 1 wherein said material is one of a conductive fluid or a non-conductive fluid.

3. The system according to claim 1 wherein said material is conductive ink and said print head deposition at said locations provides traces along the array in a first layer.

4. The system according to claim 3 wherein said print head deposition at said locations further provide contact points upon each of the elements of the array in a second layer in connection to traces of said first layer.

5. The system according to claim 1 wherein said material is a conductive material and said print head deposits conductive elements along the array to provide connections at said locations along said array.

6. The system according to claim 1 wherein said material is non-conductive material and said print head deposits said material at said locations between adjacent ones of said array elements.

7. The system according to claim 1 wherein said material has viscosity enabling dispensing via said print head.

8. The system according to claim 1 wherein said system has first and second modes, and in said first mode said material is non-conductive material and said print head deposits said material at a first plurality of said locations represent locations between adjacent different ones of said array elements, and then in said second mode said material is a conductive material and said print head deposits conductive elements along the array in one or more of traces or drops to provide connections at a second plurality of said locations representing locations along different ones of said elements of said array, in which said non-conductive material deposited prevents unintended connection of deposited conductive material to one or more of said elements of said array.

9. The system according to claim 1 wherein said print head is an ink jet print head.

10. The system according to claim 1 wherein said array has filler material between elements of said array binding said elements of said array.

11. The system according to claim 1 wherein said array is utilized as part of a finger print sensor.

12. The system according to claim 1 further comprising means for facilitating sintering of said material deposited.

13. The system according to claim 1 further comprising means for optically aligning said print head with the elements of said array.

14. A method for depositing material on an array of elements composed of electro-ceramic composite material and binding material between said elements, said method comprising the step of:
printing conductive material along the array to provide conductor elements to different ones of said elements of the array.

15. The method according to claim 14 further comprising the step of printing non-conductive material onto said array prior to said printing conductive material step at locations along the array which prevents unintended connection of said conductive material when said printing conductive material step is carried out.

16. The method according to claim 14 wherein said printing in by an ink jet printer.

17. The method according to claim 14 wherein said printing step is carried out in one or more layers upon the array.

18. The method according to claim 14 wherein said printing step is carrying out by a print head movable along said array, and said method further comprises the step of:
optically aligning said print head to one or more of said array elements prior to carrying out said printing step along said one or more of said array elements.

19. The method according to claim 14 wherein said printing step is carried in one or more of traces along the array and connection points to individual elements of the array.

20. A method for fabricating an electro-ceramic array comprising the steps of:
printing electro-ceramic material in dots upon a substrate at array locations to a height greater than a target thickness to provide elements of said array;
sintering each of the elements of said array;
applying filler material between and over the elements formed by the printing step; and
grinding the array along the top thereof until the target array thickness upon the substrate is reached.

21. The method according to claim 20 further comprising the step of printing conductive material along the array to provide connections along different ones of said elements of said array.

22. The method according to claim 20 further comprising the step of printing non-conductive material between adjacent ones of said array elements.

23. The method according to claim 22 further comprising the step of printing conductive material along the array to provide connections along different ones of said elements of said array in which said non-conductive material deposited prevents unintended connection of deposited conductive material to one or more of said elements of said array.

24. The method according to claim 20 wherein said sintering step is providing by applying a laser to each of the elements of said array.
